(19) United States
(12) Patent Application Publication
(10) Pub. No.: US 2026/0223503 A1
(43) Pub. Date: Jul. 30, 2026

(54) TRANSFER METHOD FOR TRANSFERRING ELECTRONIC COMPONENTS AND ELECTRONIC ARRANGEMENT

(71) Applicant: ams-OSRAM International GmbH, Regensburg (DE)

(72) Inventor: Thomas Schwarz, Regensburg (DE)

(21) Appl. No.: 19/145,499

(22) PCT Filed: Jan. 16, 2024
(86) PCT No.: PCT/EP2024/050866

§ 371 Date: Jul. 3, 2025

(30) Foreign Application Priority Data
Jan. 19, 2023 (DE) 10 2023 101 327.0

(51) Int. Cl. H10H 29/03; H10P 56/00

(52) U.S. Cl. CPC H10H 29/03; H10P 56/00

(57) ABSTRACT

In an embodiment a method includes providing a first substrate with a plurality of electronic components arranged in rows and columns on the first substrate, arranging a plurality of auxiliary carriers next to one another and at a distance from one another opposite the plurality of electronic components, a release layer being provided between the electronic components and the auxiliary carriers, pressing the plurality of auxiliary carriers onto the electronic components such that in each case one auxiliary carrier contacts a subset of the plurality of electronic components by the release layer, lifting off the electronic components contacted by the release layer from the first substrate, arranging the plurality of auxiliary carriers with the electronic components contacted by the release layer in an objectionable manner with respect to the second substrate and detaching the electronic components contacted by the release layer from the release layer by a LIFT process such that the detached electronic components are transferred to a second substrate.

### CROSS-REFERENCE TO RELATED APPLICATIONS

This patent application is a national phase filing under section 371 of PCT/EP2024/050866, filed Jan. 16, 2024, which claims the priority of German patent application no. 10 2023 101 327.0, filed Jan. 19, 2023, each of which is incorporated herein by reference in its entirety.

### TECHNICAL FIELD

The present invention relates to a transfer method for transferring electronic components and to an electronic arrangement.

### BACKGROUND

When transferring electronic components, such as μ-LEDs, for example, from a first substrate, in particular the wafer on which the μ-LEDs have been grown or manufactured, to a second substrate, in particular the final or target substrate on which the μ-LEDs are arranged, at least some of the following problems often occur with currently known methods:
Tilting and/or distortion of the electronic components when the electronic components are placed on the second substrate;
Low to very low buffering when lifting the electronic components when using a (thin, hard) LIFT release layer, which can lead to damage/defects in the electronic components; High yield losses in the event of defects and particles caused by damage;
Low transfer yield with small chip-to-chip distance of the electronic components on the first substrate;
Damage to holding structures of the electronic components on the first substrate when the electronic components are lifted off; and
Low adhesion of the electronic components to a transfer tool used.

A common process that deals with the problems mentioned above is, for example, the transfer of μ-LEDs using micro transfer printing (μ-TP). A polydimethylsiloxane (PDMS) stamp is used to pick up electronic components and place them on the second substrate. However, the PDMS stamp usually comprises only small dimensions compared to the dimensions of the first substrate, and the PDMS stamp is usually used to selectively remove only a few electronic components from the first substrate and already at the chip-to-chip distance required on the second substrate, so that such a process is very slow.

Another process that attempts to address the problems mentioned above is a laser induced forward transfer (LIFT) process. In this process, the electronic components are arranged either on a dynamic release layer (DRL) or a decomposition layer and transferred from there individually to the second substrate by means of selective irradiation with laser light. For example, the dynamic release layer or the decomposition layer is with laser light in certain areas so that, in the case of the DRL, a bubble is formed in the area of the irradiation, which releases the electronic component from the DRL, or so that, in the case of the decomposition layer, a gas volume is generated which releases the electronic component directly from the decomposition layer.

However, the electronic components must be transferred from the first substrate to the DRL or decomposition layer before the LIFT process, which is usually done using μ-TP. However, as already mentioned, such a transfer is very slow and therefore associated with high costs.

Another possibility for transferring the electronic components from the first substrate to the DRL or decomposition layer before the LIFT process is to press an intermediate wafer, which has a large surface area corresponding to the size of the first substrate and is coated with the DRL or decomposition layer, onto the electronic components and to detach the electronic components from the first substrate using this intermediate wafer. According to the above-mentioned disadvantages, however, this can lead to damage to retaining structures of the electronic components on the first substrate when the electronic components are lifted off, to electronic components adhering poorly to the intermediate wafer at least in part due to insufficient contact pressure by the intermediate wafer, and at the same time to electronic components being damaged due to excessive contact pressure by the intermediate wafer, since no uniform contact pressure can be achieved on the electronic components over the entire surface of the large-area intermediate wafer.

### SUMMARY

Embodiments provide a transfer method for transferring electronic components that eliminates at least some of the problems mentioned at the beginning. Further embodiments provide an electronic arrangement by which such a transfer is possible.

Embodiments provide small platelets/auxiliary carriers arranged side by side instead of a large intermediate wafer in order to lift off electronic components on a first substrate simultaneously and in large numbers from the first substrate. A release layer such as a DRL or decomposition layer is provided between the platelets/auxiliary carriers and the electronic components, so that the electronic components are arranged directly on the DRL or decomposition layer by lifting them off. The plates/auxiliary carriers are connected to each other.

By using small plates/auxiliary carriers arranged next to each other instead of a large intermediate wafer, the contact pressure on the individual small plates causes them to adapt to the profile of the electronic components on the first substrate, for example by tilting them slightly towards each other. This means that the electronic components are less damaged due to the more even contact pressure and at the same time adhere better to the release layer. With a large-area intermediate wafer, on the other hand, it is difficult to generate such a uniform contact pressure on the electronic components. In addition, the connection of the plates/auxiliary carriers ensures that all or a very large number of the electronic components can be lifted from the first substrate in one step and that the plates/auxiliary carriers are still held in position relative to each other.

According to a first aspect, a transfer method for transferring electronic components from a first substrate to a second substrate comprises the steps of:
Providing the first substrate with a plurality of electronic components arranged in rows and columns on the first substrate;
Arranging a plurality of auxiliary carriers arranged next to one another and at a distance from one another opposite the plurality of electronic components, a release layer being provided between the electronic components and the auxiliary carriers;
Pressing the plurality of auxiliary carriers onto the electronic components in such a way that one auxiliary carrier in each case contacts a subset of the plurality of electronic components by means of the release layer;
Lifting of the electronic components contacted by means of the release layer from the first substrate;
Arranging the plurality of auxiliary carriers with the electronic components contacted by means of the release layer opposite the second substrate; and
Detaching the electronic components contacted by means of the release layer from the release layer by means of a LIFT process in such a way that the detached electronic components are transferred to the second substrate at a desired distance from one another.

The electronic components can be formed in particular by optoelectronic components such as μ-LEDs. μ-LEDs can be light-emitting diodes (LEDs) that are designed to emit light of a desired wavelength and comprise particularly small dimensions. For example, μ-LEDs can comprise edge lengths of less than 100 μm, less than 50 μm or less than 10 μm and an emission area of less than 0.01 mm², less than 2500 μm² or less than 100 μm². However, the electronic components can also be formed by other electronic components such as integrated circuits (ICs) or micro-integrated circuits (μ-ICs).

According to some aspects, the auxiliary carriers are transparent, in particular transparent to light in the UV range. For example, the auxiliary carriers may comprise a glass or be formed by a glass, such as quartz glass. Alternatively or additionally, the auxiliary carriers may comprise or be formed by sapphire. In particular, the auxiliary carriers comprise a material that is transparent, especially transparent for light in the UV range. Such a design makes it possible to detach the electronic components contacted by means of the release layer from the release layer by means of a LIFT process by irradiating through the auxiliary carriers.

According to some aspects, the plurality of electronic components is grown on the first substrate. Accordingly, the first substrate may be the growth substrate of the plurality of electronic components, for example in the form of a wafer. The electronic components are arranged on the first substrate in rows and columns. In particular, the electronic components are arranged on the first substrate in a manner that is most suitable for manufacturing the electronic components on the first substrate. For example, the electronic components on the first substrate can be laterally separated from each other by a mesa etching process. However, it is also conceivable that the first substrate is a substrate onto which the electronic components have been re-bonded during their manufacture.

According to some aspects, the release layer comprises a light absorption layer. A light absorption layer can be characterized in particular by the fact that it is not or only barely transparent to light of certain wavelength(s), but absorbs the light of these wavelength(s). Due to the absorption of light, the light absorption layer can heat up locally in the area of irradiation, which can lead to the light absorption layer expanding locally, outgassing locally or even decomposing locally in the area of irradiation. In some aspects, the light absorption layer can also be called a decomposition layer.

According to some aspects, the release layer comprises, in addition to the light absorption layer, an adhesive layer and a backing layer, wherein the backing layer is arranged between the adhesive layer and the light absorption layer. Such a release layer can also be called a DRL. By means of the adhesive layer, the release layer can adhere to the auxiliary carriers, for example, and the electronic components can adhere to the light absorption layer, for example.

According to some aspects, the auxiliary carriers are flexibly connected to one another. The flexible connection of the auxiliary carriers ensures that all or a very large number of the electronic components can be lifted simultaneously from the first substrate in one step or with one lifting tool and that the individual auxiliary carriers are nevertheless held in position relative to one another by the flexible connection.

According to some aspects, the auxiliary carriers are connected to one another by a carrier tape. The carrier tape can be formed by a tape arranged on the auxiliary carriers opposite the release layer, which is transparent, in particular for light in the UV range, and which is connected to the auxiliary carriers, for example by means of an adhesive layer. The carrier tape can, for example, be arranged on the auxiliary carriers after the auxiliary carriers have been arranged on the electronic components. Before or after the step of arranging the carrier tape, the step of pressing the plurality of auxiliary carriers onto the electronic components can take place in such a way that in each case one auxiliary carrier contacts a subset of the plurality of electronic components by means of the release layer. The carrier tape can be used, for example, to enable the step of pressing the plurality of auxiliary carriers onto the electronic components via a vacuum between the carrier tape and the electronic components, or via a fluid pressure on a side of the carrier tape opposite the electronic components. At the same time, the carrier tape can be used to lift all the auxiliary carriers and thus all or a very large number of the electronic components from the first substrate at the same time in a single step or with a lifting tool and to hold the individual auxiliary carriers in position relative to one another by the connection. The transparent version of the carrier tape is used to detach the electronic components contacted by the release layer from the release layer by means of a LIFT process by irradiation through the carrier tape and through the auxiliary carriers.

The carrier tape can be formed by or comprise a flexible layer, such as a PET or PVC film, and connect the auxiliary carriers to each other in a correspondingly flexible manner, or the carrier tape can be formed by or comprise a stiffer/harder layer, such as a quartz glass or sapphire layer, and connect the auxiliary carriers to each other in a correspondingly substantially rigid manner. A combination of a flexible and a hard layer is also possible. In the event that the elasticity of the carrier tape is required, for example to apply uniform pressure to the electronic components, a hard layer of the carrier tape made of quartz glass, for example, can be laminated onto the more flexible layer at a later stage. The advantage of this is that, in contrast to a flexible connection, auxiliary carriers are arranged more precisely in one plane due to the harder layer and remain arranged more precisely in relation to each other.

According to some aspects, the auxiliary carriers are flexibly connected to each other by the release layer. The release layer can, for example, be formed by a continuous layer which is arranged between the auxiliary carriers and the electronic components and on which the auxiliary carriers are arranged at a distance from one another. The release layer can be stretched above the electronic components, for example, and the auxiliary carriers can be pressed onto the stretched release layer so that contact is made between the auxiliary carriers and the release layer and then between the release layer and the electronic components. The release layer can also fulfill the function that in one step, or with a lifting tool, all the auxiliary carriers and thus all or a very large number of the electronic components can be lifted off the first substrate at the same time and used to hold the individual auxiliary carriers in position relative to one another by the flexible connection.

According to some aspects, the release layer is structured. In particular, the release layer can be structured in such a way that areas of the release layer are only arranged between the auxiliary carriers and the electronic components and areas between the auxiliary carriers remain free of the release layer. The release layer can accordingly be formed by “individual segments”, each of which is arranged on the auxiliary carriers.

According to some aspects, the electronic components detached from the release layer and transferred to the second substrate comprise a different spacing on the second substrate than the electronic components arranged in rows and columns on the first substrate. The spacing on the second substrate may, for example, correspond to a desired pixel pitch on the second substrate, whereas the spacing of the electronic components on the first substrate may correspond to a very small spacing from one another, in particular a spacing with which the electronic components on the first substrate have been produced relative to one another. The spacing of the electronic components on the second substrate can be greater, and in particular many times greater, than the spacing of the electronic components on the first substrate.

According to some aspects, the step of detaching, in particular by the LIFT process, generates a bubble between a corresponding auxiliary carrier and an electronic component to be detached, so that the electronic component is detached from the release layer. In particular, local irradiation of the release layer can form a bubble in the irradiated area between the auxiliary carrier and the electronic component, so that the contact area between the release layer and the electronic component is changed, in particular reduced in size, and the electronic component detaches from the release layer. The release layer can, for example, be formed by a DRL in accordance with the above aspects.

According to some aspects, the step of detaching comprises simultaneously detaching a plurality of electronic components. In particular, the LIFT method/process can be used to simultaneously detach multiple electronic components from the release layer by simultaneously irradiating multiple areas. Alternatively, however, it is also possible to detach the electronic components sequentially from the release layer.

According to some aspects, the step of pressing the auxiliary carriers onto the electronic components comprises generating a vacuum and/or a fluid pressure lamination step and/or a gas pressure lamination step and/or a pin pressure lamination step. The generation of a vacuum and/or a fluid pressure lamination step may be particularly suitable when a carrier tape is used by means of which the auxiliary carriers are bonded together on an upper surface thereof. A laminating step using liquid pressure and/or a laminating step using pin pressure may be suitable, for example, if the release layer flexibly connects the auxiliary carriers to one another and has a large surface area. However, it is understood that other common methods for applying a uniform pressure to the auxiliary carriers or the release layer can also be used, even if they are not explicitly mentioned here.

According to some aspects, the step of arranging the plurality of auxiliary carriers arranged next to one another and spaced apart from each other relative to the plurality of electronic components comprises tensioning the release layer by means of a device above the electronic components, and arranging the auxiliary carriers side by side and spaced apart from each other on the tensioned release layer. The fixture for clamping can, for example, comprise a frame into which the circumferential outer edge of the release layer is clamped. Such a device can also be called a “grip ring”, for example.

According to some aspects, the step of pressing the plurality of auxiliary carriers onto the electronic components comprises pressing the tensioned release layer onto the electronic components, for example by pressing the auxiliary carriers onto the release layer by means of individual or interconnected pins, or by means of a fluid that presses onto the auxiliary carriers and the release layer.

According to some aspects, the step of lifting the electronic components contacted by the release layer from the first substrate comprises detaching the electronic components from the first substrate by means of laser light. For example, the electronic components may be attached to the first substrate by means of a patterned layer or a decomposition layer, the first layer may be transparent to laser light, and the electronic components may be detachable from the first layer by localized irradiation of the patterned layer or the decomposition layer. The electronic components can be detached from the first layer in the same way as the step of detaching the electronic components from the release layer by means of a LIFT process.

According to some aspects, the step of lifting the electronic components contacted by the release layer from the first substrate comprises selectively lifting electronic components such that the lifted electronic components on the auxiliary carriers comprise a different spacing from each other than the electronic components arranged in rows and columns on the first substrate. For example, only every second, third, fourth or other electronic component per row and column can be lifted from the first substrate in one step, so that the distance between the electronic components on the auxiliary carriers is different, in particular greater, than the distance between the electronic components on the first substrate.

According to some aspects, selectively detaching electronic components comprises selectively detaching electronic components from the first substrate by means of laser light selectively irradiated through the first substrate. By (simultaneously) irradiating only every second, third, fourth or other electronic component per row and column on the first substrate, in particular through the first substrate, selectively selected electronic components can be detached from the first substrate by means of the release layer and transferred to the second substrate.

According to some aspects, the release layer is structured in the regions between an auxiliary carrier and the electronic components. In particular, the release layer is structured in these regions such that only unstructured regions of the release layer selectively contact a subset of the electronic components on the first substrate during the step of pressing the plurality of auxiliary carriers onto the electronic components. In the case of a DRL, for example, the carrier layer and/or the light absorption layer can be structured in such a way that unstructured areas comprise a greater thickness than structured areas, and thus only unstructured thicker areas come into contact with electronic components when the release layer is pressed onto the electronic components.

According to a further aspect, an electronic arrangement comprises a plurality of auxiliary carriers arranged next to one another and spaced apart from one another, which are connected to one another by a carrier strip, wherein the auxiliary carriers are transparent to light, in particular to light in the UV range. The arrangement also comprises a plurality of electronic components arranged on the auxiliary carriers in rows and columns, wherein a release layer is arranged between the electronic components and the auxiliary carriers, and wherein the release layer comprises at least one light absorption layer which at least partially decomposes when exposed to light, in particular light in the UV range. A tensioning device, which is attached to the edges of the carrier tape, tensions the carrier tape between its edges and allows the electronic arrangement to be accommodated.

The electronic arrangement can, for example, be an intermediate product of the method according to the invention, namely an arrangement comprising the auxiliary carriers, the release layer, optionally the carrier tape, and the electronic components arranged on the release layer after these have been lifted from the first substrate and before these are transferred to the second substrate. The arrangement also comprises a device/frame by means of which the release layer and/or the carrier tape are clamped and by means of which the electronic arrangement can be picked up by a tool for further processing. In contrast to the transfer method according to the invention, however, the general term “carrier tape” in the arrangement according to the invention can mean the release layer as it is referred to in the transfer method according to the invention, or it can mean the carrier tape as it is referred to in the transfer method according to the invention.

According to some aspects, the carrier tape comprises the separation layer. In particular, the carrier tape comprises the release layer in the event that the release layer is formed by a continuous layer which is arranged between the auxiliary carriers and the electronic components and on which the auxiliary carriers are arranged at a distance from one another. In this case, the auxiliary carriers are flexibly connected to each other by the release layer and no separate/additional carrier tape is required on the upper sides of the auxiliary carriers. However, the electronic arrangement can also comprise a continuous release layer and an additional carrier tape.

According to some aspects, the release layer comprises, in addition to the light absorption layer, an adhesive layer and a backing layer, wherein the backing layer is arranged between the adhesive layer and the light absorption layer. In particular, the release layer may be formed by a DRL.

According to some aspects, the carrier tape is arranged on one side opposite the release layer of the auxiliary carriers. In this case, the auxiliary carriers are connected to each other by the carrier tape, i.e. by a separate/additional tape on the upper sides of the auxiliary carriers. The carrier tape is transparent, in particular transparent for light in the UV range, so that it is possible to irradiate the electronic components with laser light, in particular laser light in the UV range, through the carrier tape and the auxiliary carriers.

According to some aspects, the tensioning device is attached to edges of the release liner, and the tensioning device also tensions the release liner between its edges. Accordingly, the release liner and/or the carrier tape can be clamped and tensioned by the tensioning device.

According to some aspects, the release layer is structured in such a way that the release layer only covers the auxiliary carriers and areas between the auxiliary carriers remain free of the release layer. Accordingly, the release layer can be formed by “individual segments”, each of which is arranged on the auxiliary carriers.

According to some aspects, the release layer between an auxiliary carrier and the electronic components arranged thereon is structured such that regions of the release layer between the electronic components on the release layer are at least partially removed. In particular, the release layer is structured in these areas in such a way that only unstructured areas of the release layer selectively contact a subset of the electronic components on the first substrate during the step of pressing the plurality of auxiliary carriers onto the electronic components. In the case of a DRL, for example, the carrier layer and/or the light absorption layer can be structured in such a way that unstructured areas comprise a greater thickness than structured areas, and thus only unstructured thicker areas come into contact with electronic components when the release layer is pressed onto the electronic components.

The method and arrangement according to embodiments of the invention can result in the following advantages:
Homogeneous pressure distribution on the electronic components to be lifted off the first substrate→High lamination performance
Tilt compensation through the use of individual auxiliary carriers→High transfer yield
Simple process chain with just a few process steps (no μ-TP required)→Low costs
Compatible with existing μ-LEDs→Low chip development costs.

### BRIEF DESCRIPTION OF THE DRAWINGS

Further aspects and embodiments according to the proposed principle will become apparent with reference to the various embodiments and examples described in detail in connection with the accompanying drawings.

FIGS. 1A to 1F show steps of a transfer process according to some aspects of the proposed principle;

FIGS. 2A and 2B show steps of a further embodiment of a transfer method according to some aspects of the proposed principle;

FIGS. 3A to 3F show steps of a further embodiment of a transfer method according to some aspects of the proposed principle;

FIGS. 4A to 4D show steps of a further embodiment of a transfer method according to some aspects of the proposed principle;

FIGS. 5A and 5B show steps of a further embodiment of a transfer method according to some aspects of the proposed principle;

FIG. 6 shows an electronic arrangement according to some aspects of the proposed principle;

FIGS. 7A and 7B show steps of a further embodiment of a transfer method according to some aspects of the proposed principle;

FIGS. 8A and 8B show steps of a further embodiment of a transfer method according to some aspects of the proposed principle;

FIGS. 9A and 9B show steps of another embodiment of a transfer method according to some aspects of the proposed principle; and

FIGS. 10A and 10B show steps of a further embodiment of a transfer method according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects comprise a regular structure or shape. It should be noted that slight deviations from the ideal shape may occur in practice without, however, contradicting the inventive concept.

In addition, the individual figures, features and aspects are not necessarily shown in the correct size, and the proportions between the individual elements do not necessarily have to be correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

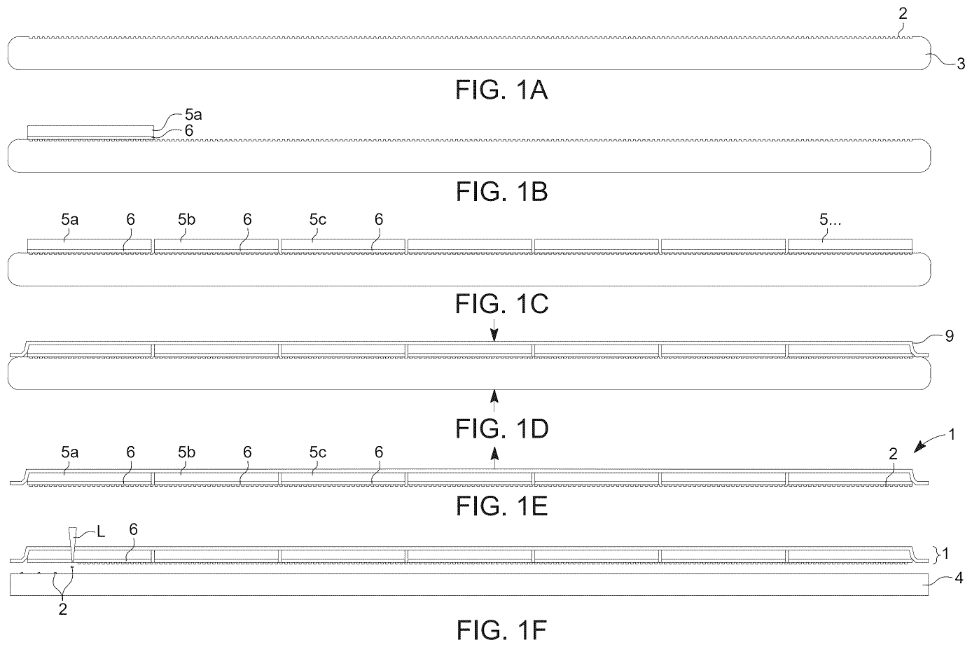

FIGS. 1A to 1F each show a side view of steps of a transfer method for transferring electronic components 2 from a first substrate 3 to a second substrate 4 according to some aspects of the proposed principle.

In a first step, as shown in FIG. 1A, a first substrate 3 with a plurality of electronic components 2 arranged in rows and columns is provided. The electronic components may in particular be μ-LEDs that have been produced on the first substrate 3. The first substrate 3 can, for example, be the growth substrate/manufacturing wafer of the electronic components 2. The electronic components are arranged in rows and columns on the first substrate 3. In particular, the electronic components 2 are arranged on the first substrate 3 in such a way as may result from manufacturing the electronic components 2 on the first substrate 3.

In a subsequent step, as shown in FIGS. 1B and 1C, auxiliary carriers 5a, 5b, 5c, 5 . . . are successively arranged adjacent to and spaced apart from one another on a respective subset of the electronic components 2. A part of a release layer 6, by means of which the electronic components 2 are contacted, is located on an underside of each of the auxiliary carriers. The release layer 6 is designed in particular so that electronic components 2 adhere to it when the release layer 6 is pressed onto the electronic components 2, and so that electronic components 2 adhering to the release layer 6 can be detached from the release layer 6 again by means of laser light L. The release layer 6 can be a DRL or a decomposition layer, for example. Various embodiments of the release layer 6 will be discussed below.

The auxiliary carriers 5a, 5b, 5c, 5 . . . are each made of a transparent material, such as glass or sapphire, so that the electronic components 2 adhering to the release layer 6 can be detached from the release layer 6 by means of laser light L shone through the auxiliary carriers. The number of auxiliary carriers shown is merely exemplary. The use of the reference sign “5 . . . ” for the rightmost of the auxiliary carriers is intended to indicate that the number of auxiliary carriers can be selected in the direction shown from left to right, as well as in the direction of the drawing plane, depending on the application and requirements. The number of auxiliary carriers can depend on the size of the first substrate and the size of the auxiliary carriers. The size of the auxiliary carriers can, for example, correlate with existing markers on the first substrate 3 grown with the electronic components 2. In particular, so-called “reticle areas” can be located on the first substrate 3. These are neighboring areas that are exposed one after the other in an exposure during the manufacture of the electronic components. A typical reticle size is between 15 mm×15 mm and 25 mm×25 mm. Alignment marks and/or test structures can also be located between the reticle areas. For example, the size of an auxiliary carrier can be 20 mm×20 mm.

In a subsequent step, as shown in FIG. 1D, a carrier tape 9 is applied to the upper sides of the auxiliary carriers 5a, 5b, 5c, 5 . . . , by means of which the auxiliary carriers 5a, 5b, 5c, 5 . . . are joined together. The carrier tape 9 extends over a large area over the entire surface of the auxiliary carriers 5a, 5b, 5c, 5 . . . , as well as along the side surfaces of the outermost auxiliary carriers up to the first substrate 3. In particular, in the embodiment shown, the carrier tape is designed and arranged in such a way that it seals airtightly with the first substrate 3, so that a vacuum can be generated between the carrier tape 9 and the first substrate 3.

With the aid of the carrier tape 9, the auxiliary carriers 5a, 5b, 5c, 5 . . . with the segments of the release layer 6 arranged thereon are then pressed onto the electronic components 2 (shown by the two arrows). For this purpose, either a vacuum can be generated between the carrier tape 9 and the first substrate 3 and/or a fluid can be used to apply uniform pressure to the upper side of the carrier tape 9 opposite the auxiliary carriers.

The evenly applied pressure by means of vacuum and/or fluid pressure in combination with the fact that the many individual auxiliary carriers are connected to each other means that irregularities in the profile on the upper side of the electronic components 2 can be compensated for. This is due to the fact that the auxiliary carriers can tilt slightly in relation to each other, for example, so that a more even pressure is applied to the electronic components 2 compared to a large-area and continuous auxiliary carrier. As a result, all or at least a larger number of electronic components 2 make better contact with the release layer 6 and adhere better to it.

In a subsequent step, as shown in FIG. 1E, the electronic components 2 adhering to the release layer 6 are lifted off the first substrate 3 (shown by the arrow in FIG. 1E). For this purpose, the auxiliary carriers 5a, 5b, 5c, 5 . . . connected to the carrier tape 9 are lifted off the first substrate 3 together with the segments of the release layer 6 located thereon and the electronic components 2 located thereon. By means of each auxiliary carrier 5a, 5b, 5c, 5 . . . or each segment of the release layer 6 located on the auxiliary carrier, a partial quantity of the plurality of electronic components 2 is lifted from the first substrate 3. With a size of approx. 20 mm×20 mm of an auxiliary carrier and an edge length of approx. 50 μm of the electronic components 2, for example, approx. 400×400=160,000 electronic components 2 can be lifted from the first substrate by means of an auxiliary carrier. Alternatively, the electronic components 2 can also be lifted off by pulling the first substrate 3 downwards.

The resulting “intermediate product” according to FIG. 1E corresponds to an electronic arrangement 1 according to some aspects of the proposed principle (clamping device not shown here). The electronic arrangement 1 can be used to equip a second substrate 4 with electronic components 2 as described below.

For this purpose, as shown in FIG. 1F, the auxiliary carriers 5a, 5b, 5c, 5 . . . connected by means of the carrier tape with the electronic components 2 contacted by means of the release layer 6 are arranged at a distance from a second substrate 4. By means of a LIFT process, the electronic components 2 contacted by means of the release layer 6 are then detached from the release layer 6 in such a way that the detached electronic components 2 are transferred to the second substrate 4 at a desired distance from one another, in particular by falling from the first substrate 3 onto the second substrate 4. The electronic components 2 or the release layer 6 between the electronic components 2 and the auxiliary carriers are irradiated with laser light L locally through the carrier tape and the auxiliary carriers 5a, 5b, 5c, 5 . . . so that the electronic components 2 are detached from the release layer and transferred to the second substrate 4. The laser light can be pulsed laser light in the UV range, for example.

The electronic components 2 detached from the release layer 6 and transferred to the second substrate 4 comprise a different spacing from each other on the second substrate 4 than the electronic components 2 arranged in rows and columns on the first substrate 3. The spacing on the second substrate 4 may, for example, correspond to a desired pixel pitch on the second substrate 4, whereas the spacing of the electronic components 2 on the first substrate 3 may correspond to a very small spacing from one another, in particular a spacing with which the electronic components 2 on the first substrate 3 have been produced relative to one another. The distance between the electronic components 2 on the second substrate 4 is greater, in particular many times greater, than the distance between the electronic components 2 on the first substrate 3.

The spacing of the electronic components 2 on the second substrate 4 can be achieved, for example, by merely detaching each second, third, fourth or other electronic component 2 per auxiliary carrier and dropping it onto the second substrate 4, or by moving the auxiliary carriers parallel to the second substrate 4 and detaching electronic components 2 at a correspondingly provided position above the second substrate 4 so that they are transferred to the correspondingly provided position.

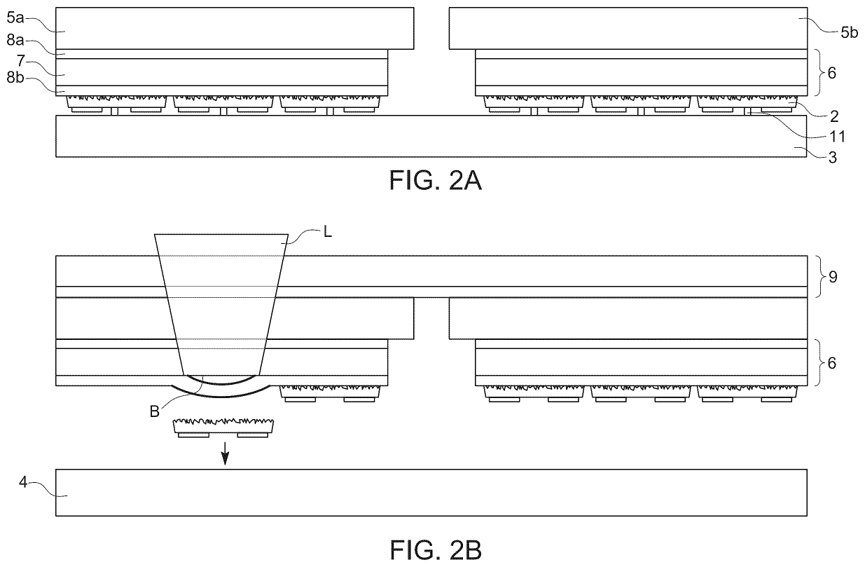

FIGS. 2A and 2B show detailed views of steps of a transfer method according to some aspects of the proposed principle. In particular, FIG. 2A shows a detailed view of the step of arranging a plurality of auxiliary carriers 5a, 5b arranged side by side and spaced apart from each other with respect to the plurality of electronic components 2, wherein a separation layer 6 is provided between the electronic components 2 and the auxiliary carriers 5a, 5b. The release layer 6 comprises a carrier layer 7, as well as an adhesive layer 8a and a light absorption layer 8b, wherein the carrier layer 7 is arranged between the adhesive layer 8a and the light absorption layer 8b. The light absorption layer 8b can be characterized in particular by the fact that it is not or only barely transparent for light of certain wavelength(s), but absorbs the light of these wavelength(s). Due to the absorption of the light, the light absorption layer can heat up locally in the area of the irradiation, which can lead to the light absorption layer expanding locally, outgassing locally or even decomposing locally in the area of the irradiation. The release layer 6 can adhere to the auxiliary carriers 5a, 5b by means of the adhesive layer 8a and the electronic components 2 can adhere to the light absorption layer 8b. Such a release layer 6 can also be called DRL.

The electronic components 2 are attached to the first substrate by means of a retaining structure 11. In the case shown, the holding structure 11 is formed by small supports on which the electronic components 2 are arranged in each case. The supports can be designed in such a way that, although they hold the electronic components 2 in position, they break when a sufficient tensile force is applied to the electronic components 2, so that the electronic components 2 can be easily detached from the first substrate 3.

FIG. 2B, on the other hand, shows a detailed view of the step of detaching the electronic components 2 contacted by means of the release layer 6 from the release layer 6 by means of a LIFT process, such that the detached electronic components 2 are transferred to the second substrate 4 at a desired distance from one another, in particular by dropping them from the first substrate 3 onto the second substrate 4. The release layer 6 and in particular the light absorption layer 8b is irradiated locally by means of laser light L, in particular laser light pulses in the UV range, so that the light absorption layer 8b expands locally, outgasses locally or even decomposes locally in the area of the irradiation. As a result, a bubble B forms in the area of the irradiation between the release layer 7 and the light absorption layer 8b and an electronic component 2 then detaches from the light absorption layer 8b. The detached electronic component 2 then falls from the release layer 6 onto the second substrate 4 (shown by the arrow in FIG. 2B).

This step can then be repeated for further electronic components 2 until the second substrate 4 is fully populated or no more electronic components 2 adhere to the release layer 6. It is also possible for several electronic components 2 to be detached from the release layer at the same time using the method shown and to be transferred to the second substrate 4 at the same time.

As shown in FIG. 2B, the carrier tape 9 may comprise an adhesive layer by means of which the carrier tape 9 is attached to the auxiliary carriers 5a, 5b. The carrier tape 9 may, for example, comprise a PET film which is attached to the auxiliary carriers 5a, 5b and thus form a flexible carrier tape 9, or the carrier tape 9 may, for example, comprise a glass layer which is attached to the auxiliary carriers 5a, 5b and thus form a rigid carrier tape 9.

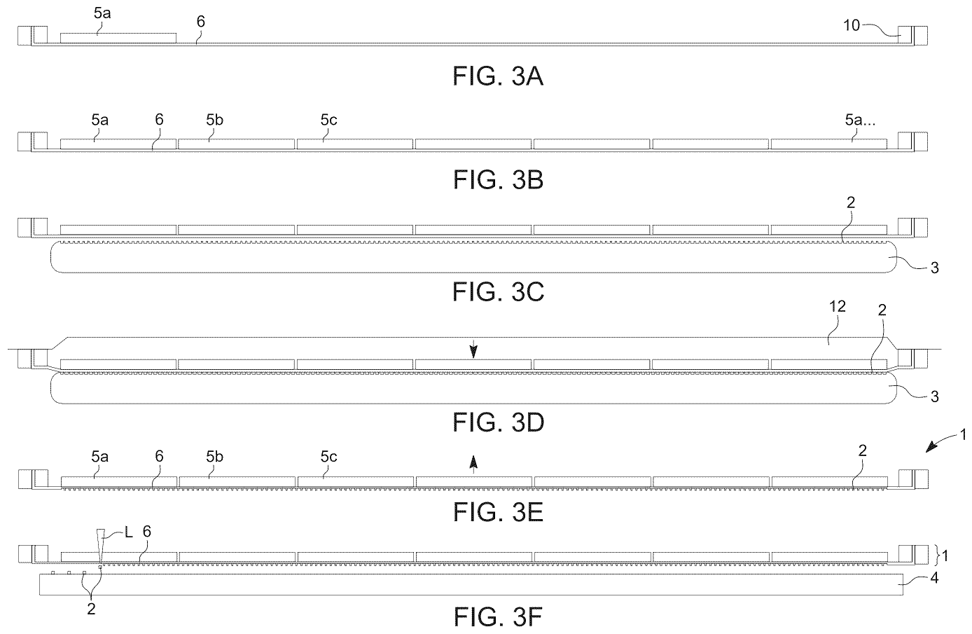

FIGS. 3A to 3F show steps of a further embodiment of a transfer method according to some aspects of the proposed principle.

As shown in FIG. 3A, in a first step a large-area and continuous release layer 6 is clamped in a clamping device 10. Subsequently, as also shown in FIG. 3B, auxiliary carriers 5a, 5b, 5c, 5 . . . are arranged next to each other and at a distance from each other on the release layer 6.

The tensioned release layer 6 with the auxiliary carriers 5a, 5b, 5c, 5 . . . arranged thereon is then, as shown in FIG. 3C, arranged at a distance from a first substrate 3 with a plurality of electronic components 2 arranged in rows and columns and positioned in such a way that the auxiliary carriers are each arranged opposite a desired subset of the plurality of electronic components 2.

Then, as shown in FIG. 3D, a cover 12 is applied to the clamping device 10 in such a way that a sealed space is created between the release layer 6 and the cover 12. A fluid can then be introduced into the sealed space, thereby generating an overpressure, so that the auxiliary carriers 5a, 5b, 5c, 5 . . . and the release layer 6 are pressed onto the electronic components 2 and contact the electronic components 2 (shown by the arrow in FIG. 3D).

The electronic components 2 contacted by means of the release layer 6 are then detached from the first substrate 3, as shown in FIG. 3E, either by pulling the tensioned release layer 6 upwards relative to the first substrate 3 and/or by pulling the first substrate 3 downwards away from the release layer 6.

The resulting “intermediate product” according to FIG. 3E corresponds to an electronic arrangement 1 according to some aspects of the proposed principle. The electronic arrangement 1 can be used to equip a second substrate 4 with electronic components 2 as already described for FIG. 1F.

For this purpose, as shown in FIG. 3F, the auxiliary carriers 5a, 5b, 5c, 5 . . . connected by means of the release layer 6 are arranged with the electronic components 2 contacted by means of the release layer 6 at a distance from the second substrate 4. By means of a LIFT process, the electronic components 2 contacted by means of the release layer 6 are then detached from the release layer 6 in such a way that the detached electronic components 2 are transferred to the second substrate 4 at a desired distance from one another, in particular by falling from the first substrate 3 onto the second substrate 4. The electronic components 2 or the release layer 6 between the electronic components 2 and the auxiliary carriers are irradiated with laser light L locally through the carrier tape and the auxiliary carriers 5a, 5b, 5c, 5 . . . so that the electronic components 2 detach from the release layer and fall onto the second substrate 4. The laser light can be pulsed laser light in the UV range, for example.

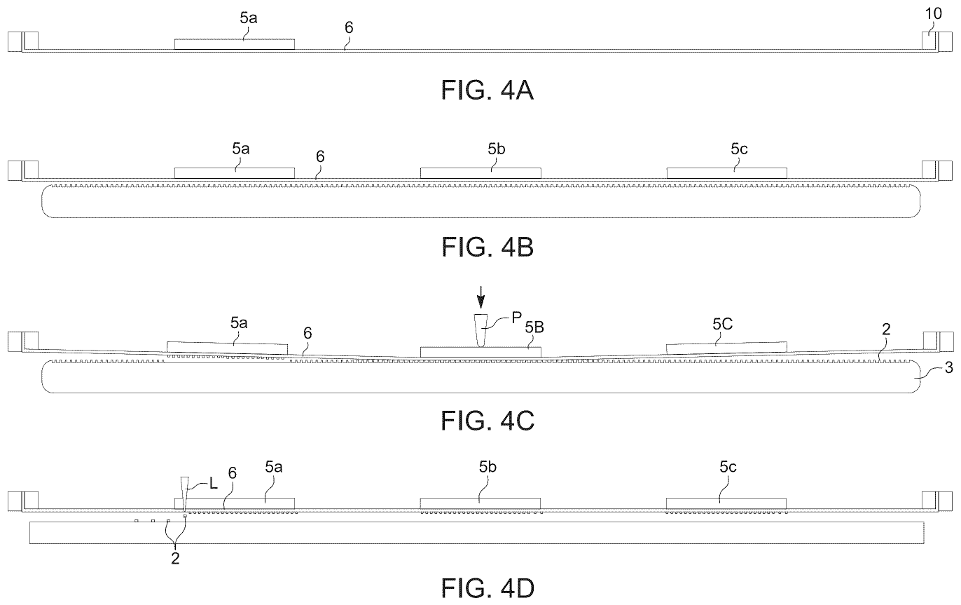

FIGS. 4A to 4D show steps of a further embodiment of a transfer method according to some aspects of the proposed principle.

In contrast to the process screens shown in FIGS. 3A to 3F, however, the auxiliary carriers 5a, 5b, 5c are arranged at a greater distance from one another on the tensioned release layer 6 (see FIGS. 4A and 4B). In addition, in contrast to the embodiment shown in FIG. 3D, the step of pressing on the auxiliary carriers 5a, 5b, 5c is not carried out by means of fluid pressure lamination, but by individually pressing on the auxiliary carriers 5a, 5b, 5c with the aid of a pin P (see FIG. 4C). Pressing on the auxiliary carriers 5a, 5b, 5c with the aid of a pin P requires that the auxiliary carriers 5a, 5b, 5c are arranged at a greater distance from one another on the tensioned release layer 6, and that the tensioned release layer 6 is arranged at a greater distance from the first substrate 3, so that when an auxiliary carrier 5b is pressed onto the first substrate 3, only the electronic components 2 that are located below the auxiliary carrier 5b and are to be lifted off by means of this auxiliary carrier 5b come into contact with the release layer 6. By proceeding in this way, it is possible to achieve in an improved manner that the auxiliary carriers or the release layer 6 adapt to a surface profile of the first substrate 3 resulting from the electronic components 2 and that a uniform pressure is applied to the electronic components 2 to be lifted off.

The electronic components 2 can then be transferred to a second substrate 4, as already described for FIGS. 1F and 3F. For this purpose, as shown in FIG. 4D, the auxiliary carriers 5a, 5b, 5c connected by means of the release layer 6 are arranged with the electronic components 2 contacted by means of the release layer 6 at a distance from the second substrate 4. By means of a LIFT process, the electronic components 2 contacted by means of the release layer 6 are then detached from the release layer 6 in such a way that the detached electronic components 2 are transferred to the second substrate 4 at a desired distance from one another, in particular by falling from the first substrate 3 onto the second substrate 4. The electronic components 2 or the release layer 6 between the electronic components 2 and the auxiliary carriers are irradiated with laser light L locally through the carrier tape and the auxiliary carriers 5a, 5b, 5c, so that the electronic components 2 detach from the release layer and fall onto the second substrate 4. The laser light can be pulsed laser light in the UV range, for example.

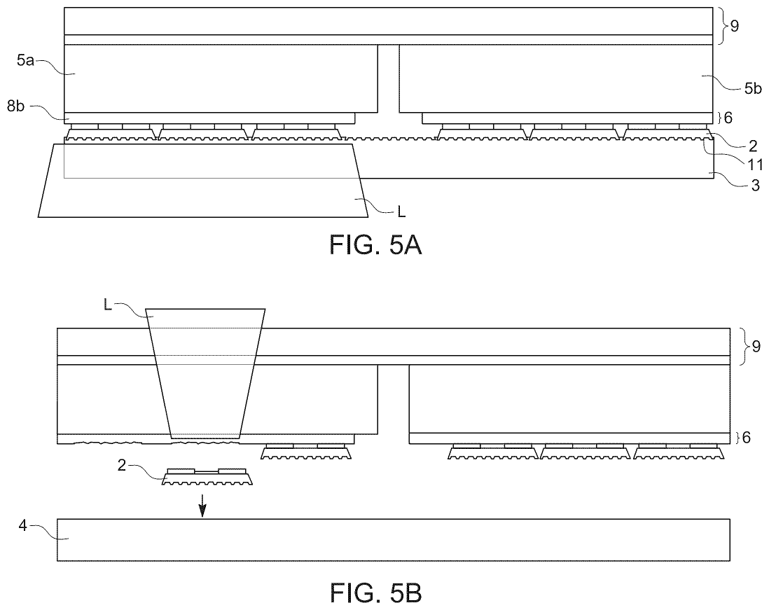

FIGS. 5A and 5B show detailed views of steps of a further embodiment of a transfer method according to some aspects of the proposed principle. In particular, FIG. 5A shows a detailed view of the step of arranging a plurality of auxiliary carriers 5a, 5b arranged side by side and spaced apart from each other with respect to the plurality of electronic components 2, wherein a release layer 6 in the form of a light absorption layer 8b or decomposition layer is provided between the electronic components 2 and the auxiliary carriers 5a, 5b. The light absorption layer 8b or decomposition layer can be characterized in particular by the fact that it is not or only barely transparent to light of certain wavelength(s), but absorbs the light of these wavelength(s). The absorption of the light can cause the decomposition layer to heat up locally in the area of the irradiation, which can lead to the light absorption layer outgassing or decomposing locally in the area of the irradiation.

The electronic components 2 are attached to the first substrate by means of a retaining structure 11. In the case shown, the holding structure 11 is formed by a light-absorbing structuring on which the electronic components 2 are arranged. The light-absorbing structuring (for example gallium nitride or silicon nitride on a structured sapphire substrate) can be designed in such a way that it holds the electronic components 2 in position, but the electronic components 2 can be detached from the first substrate 3 by local irradiation of the light-absorbing structuring 11 with laser light L. The step of detaching the electronic components 2 therefore comprises, as shown, irradiating the electronic components 2 to be detached from the first substrate 3 by means of laser light L, in particular pulsed laser light in the UV range, through the first substrate 3. The electronic components 2 detached in this way can then be lifted off the first substrate by means of the auxiliary carriers and the release layer 6.

FIG. 5B shows a detailed view of the step of detaching the electronic components 2 contacted by means of the release layer 6 from the release layer 6 by means of a LIFT process, such that the detached electronic components 2 are transferred to the second substrate 4 at a desired distance from one another, in particular by falling from the first substrate 3 onto the second substrate 4. The release layer 6 and in particular the light absorption layer 8b or decomposition layer is irradiated locally by means of laser light L, in particular laser light pulses in the UV range, so that the decomposition layer heats up in the area of the irradiation and outgasses locally or decomposes locally. The corresponding electronic component 2 then detaches from the release layer 6 and falls from the release layer 6 onto the second substrate 4 (shown by the arrow in FIG. 5B).

This step can then be repeated for further electronic components 2 until the second substrate 4 is fully populated or no more electronic components 2 adhere to the release layer 6. It is also possible for several electronic components 2 to be detached from the release layer at the same time using the method shown and to be transferred to the second substrate 4 at the same time.

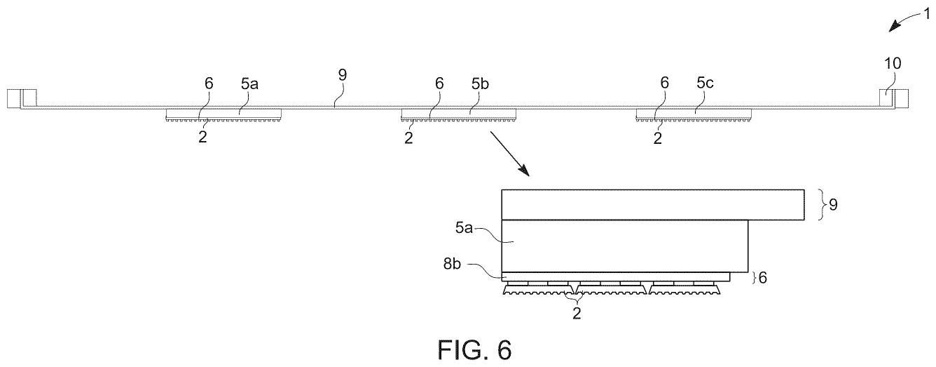

FIG. 6 shows an exemplary embodiment of an electronic arrangement 1 according to some aspects of the proposed principle. The electronic arrangement 1 comprises a plurality of auxiliary carriers 5a, 5b, 5c arranged side by side and at a distance from one another, which are connected to one another on their upper side by a carrier strip 9. However, the number of auxiliary carriers is to be understood here only as an example and can also be larger as required. A large number of electronic components 2 arranged in rows and columns are arranged on the auxiliary carriers 5a, 5b, 5c, whereby segments of a release layer 6 are arranged between the electronic components 2 and the auxiliary carriers 5a, 5b, 5c. The carrier strip 9 is fastened at its edges in the tensioning device 10 and is tensioned between its edges by the tensioning device. In addition to tensioning the carrier tape, the tensioning device is designed to allow the electronic arrangement 1 to be picked up. The lower part of FIG. 6 shows a detailed view of an auxiliary carrier 5b with electronic components 2 attached to it. In the case shown, the release layer is formed by a light absorption layer 8b to which the electronic components 2 adhere, and the carrier tape 9 comprises an adhesive layer by means of which the carrier tape adheres to the upper sides of the auxiliary carriers 5a, 5b, 5c. The auxiliary carriers 5a, 5b, 5c and the carrier tape 9 are transparent to light, in particular to light in the UV range, in order to enable irradiation of the release layer 6 and thus detachment of the electronic components from the release layer 6.

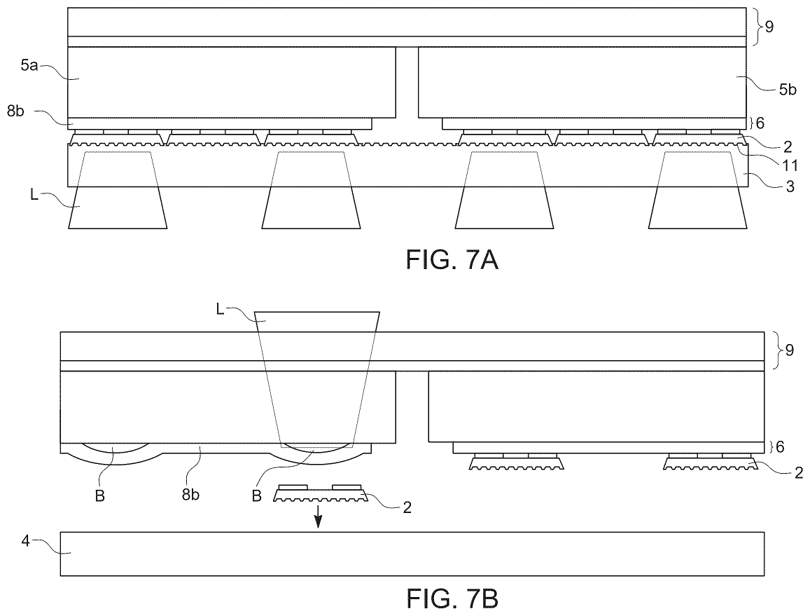

FIGS. 7A and 7B, 8A and 8B and 9A and 9B each show detailed views of steps of a further embodiment of a transfer method according to some aspects of the proposed principle, which allow selective lifting of electronic components 2 from the first substrate 3 per auxiliary carrier.

According to FIG. 7A, a selective lifting of electronic components 2 from the first substrate 3 per auxiliary carrier is achieved by the fact that only desired electronic components 2 are detached from the first substrate 3 by means of laser light L and accordingly only these detached electronic components 2 can be lifted from the first substrate 3. Detachment of the electronic components 2 contacted by means of the release layer 6 from the release layer 6 then takes place by means of a LIFT process, as already described with reference to FIG. 5B, in such a way that the detached electronic components 2 are transferred to the second substrate 4 at a desired distance from one another, in particular by falling from the first substrate 3 onto the second substrate 4. The release layer 6 and in particular the light absorption layer 8b or decomposition layer is irradiated locally by means of laser light L, in particular laser light pulses in the UV range, so that the decomposition layer heats up in the area of the irradiation and outgasses locally or decomposes locally. The corresponding electronic component 2 then detaches from the release layer 6 and falls from the release layer 6 onto the second substrate 4 (shown by the arrow in FIG. 7B).

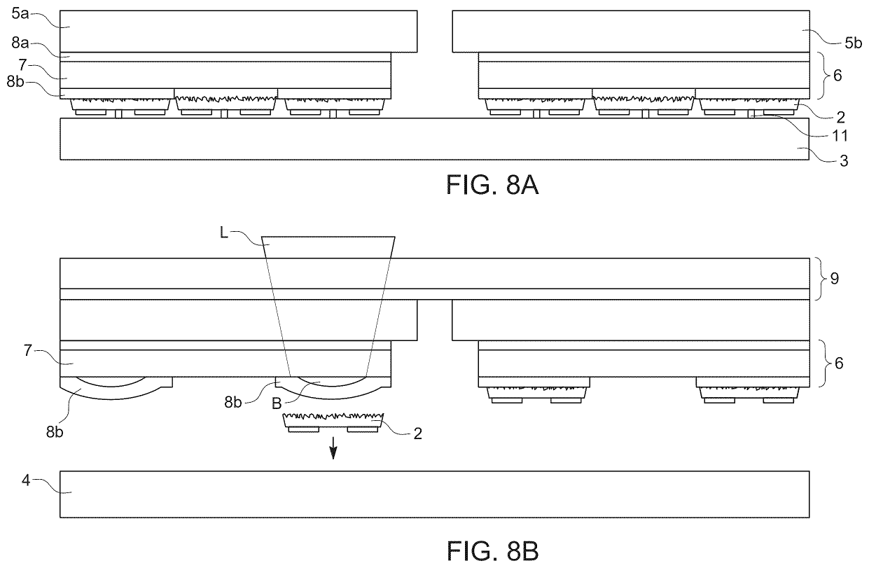

According to FIG. 8A, a selective lifting of electronic components 2 from the first substrate 3 per auxiliary carrier is achieved by the fact that the light absorption layer 8b of the release layer 6 is structured and thus only unstructured areas of the light absorption layer 8b come into contact with the electronic components 2 when the auxiliary carriers 5a, 5b are placed on the electronic components. Accordingly, only these electronic components 2 contacted by means of the light absorption layer 8b are lifted off the first substrate 3. The electronic components 2 contacted by means of the release layer 6 are then detached from the release layer 6 by means of a LIFT process, as already described with reference to FIG. 2B, in such a way that the detached electronic components 2 are transferred to the second substrate 4 at a desired distance from one another, in particular by falling from the first substrate 3 onto the second substrate 4.

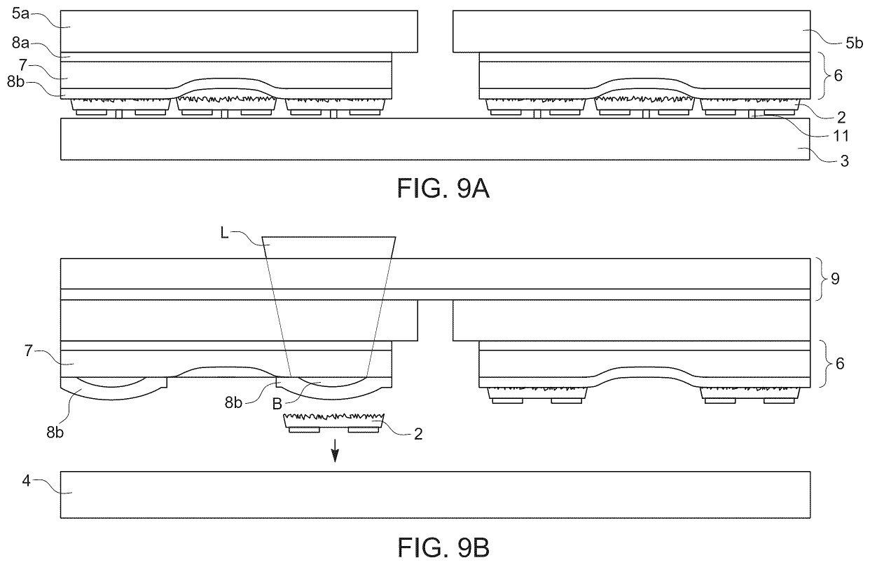

According to FIG. 9A, a selective lifting of electronic components 2 from the first substrate 3 per auxiliary carrier is achieved by the fact that the carrier layer 7 of the release layer 6 is structured and thus the light absorption layer 8b is arranged in the structured areas of the carrier layer 7 in the depressions of the carrier layer 7. Thus, when the auxiliary carriers 5a, 5b are placed on the electronic components 2, only areas of the light absorption layer 8b in which the carrier layer 7 is unstructured come into contact with the electronic components 2. Accordingly, only these electronic components 2 contacted by the light absorption layer 8b are lifted off the first substrate 3. The electronic components 2 contacted by means of the release layer 6 are then detached from the release layer 6 by means of a LIFT process, as already described with reference to FIGS. 2B and 8B, in such a way that the detached electronic components 2 are transferred to the second substrate 4 at a desired distance from one another, in particular by falling from the first substrate 3 onto the second substrate 4.

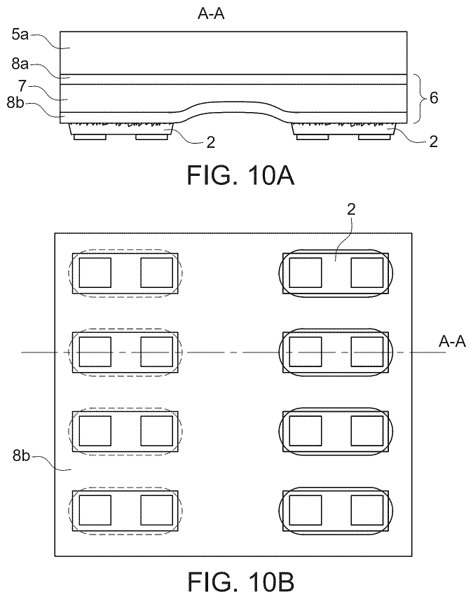

FIGS. 10A and 10B each show a detailed view of an auxiliary carrier 5b as used in the steps according to FIGS. 9A and 9B. FIG. 10A shows a sectional view of the auxiliary carrier 5a along the sectional line A-A through the auxiliary carrier 5b shown from below in FIG. 10B. The carrier layer 7 of the release layer 6 is structured or comprises recesses and the light absorption layer 8b is arranged in the structured areas of the carrier layer 7 in the recesses of the carrier layer 7. When the auxiliary carrier 5a is placed on the electronic components 2 on the first substrate 3, only areas of the light absorption layer 8b come into contact with the electronic components 2 in which the carrier layer 7 is unstructured. Accordingly, only these electronic components 2 contacted by the light absorption layer 8b are lifted off the first substrate 3. In the top view of the auxiliary carrier shown from below, these unstructured areas of the carrier layer 7 are shown by dashed ellipses in FIG. 10B. The release layer 6 comprises corresponding elliptical supports on which the light absorption layer 8b protrudes above the other areas of the release layer 6 and which come into contact with the electronic components 2 when the auxiliary carrier 5a is placed on the electronic components 2 on the first substrate 3.

1.-26. (canceled)

27. A transfer method for transferring electronic components from a first substrate to a second substrate, the method comprising:
providing the first substrate with a plurality of electronic components arranged in rows and columns on the first substrate;
arranging a plurality of auxiliary carriers next to one another and at a distance from one another opposite the plurality of electronic components, a release layer being provided between the electronic components and the auxiliary carriers;
pressing the plurality of auxiliary carriers onto the electronic components such that in each case one auxiliary carrier contacts a subset of the plurality of electronic components by the release layer;
lifting off the electronic components contacted by the release layer from the first substrate;
arranging the plurality of auxiliary carriers with the electronic components contacted by the release layer in an objectionable manner with respect to the second substrate; and
detaching the electronic components contacted by the release layer from the release layer by a LIFT process such that the detached electronic components are transferred to the second substrate at a desired distance from one another.

28. The transfer method according to claim 27, wherein the auxiliary carriers are transparent to light in an UV range.

29. The transfer method according to claim 27, wherein the plurality of electronic components are manufactured on the first substrate.

30. The transfer method according to claim 27, wherein the release layer comprises a light absorption layer.

31. The transfer method according to claim 27, wherein the auxiliary carriers are flexibly connected to each other.

32. The transfer method according to claim 31, wherein the auxiliary carriers are connected to one another by a carrier tape, wherein the carrier tape is arranged on the auxiliary carriers opposite the release layer and transparent.

33. The transfer method according to claim 31, wherein the auxiliary carriers are flexibly connected to each other by the release layer.

34. The transfer method according to claim 27, wherein the release layer is arranged in each case only between the auxiliary carriers and the electronic components, and wherein regions between the auxiliary carriers remain free of the release layer.

35. The transfer method according to claim 27, wherein the electronic components detached from the release layer and transferred to the second substrate comprise a different distance to each other on the second substrate than the electronic components arranged in rows and columns on the first substrate.

36. The transfer method according to claim 27, wherein detaching comprises generating, in each case, a bubble between a corresponding auxiliary carrier and an electronic component to be detached so that the electronic component is detached from the release layer.

37. The transfer method according to claim 27, wherein detaching comprises simultaneous detaching of several of the electronic components.

38. The transfer method according to claim 27, wherein pressing comprises generating a vacuum and/or laminating via gas pressure and/or liquid pressuring and/or a laminating via pin pressure.

39. The transfer method according to claim 27, wherein arranging the plurality of auxiliary carriers next to one another and spaced apart from each other with respect to the plurality of electronic components comprises tensioning the release layer by a device above the electronic components, and arranging the auxiliary carriers next to one another and spaced apart from each other on the tensioned release layer.

40. The transfer method according to claim 39, wherein pressing the plurality of auxiliary carriers onto the electronic components comprises pressing the tensioned release layer onto the electronic components.

41. The transfer method according to claim 27, wherein lifting off the electronic components contacted by the release layer from the first substrate comprises detaching the electronic components from the first substrate by laser light.

42. The transfer method according to claim 27, wherein lifting off the electronic components contacted by the release layer from the first substrate comprises selectively lifting off the electronic components so that the lifted-off electronic components on the auxiliary carriers comprise a different distance to each other than the electronic components arranged in rows and columns on the first substrate.

43. The transfer method according to claim 42, wherein selectively lifting off the electronic components comprises selective detaching the electronic components from the first substrate by a laser light selectively irradiated through the first substrate.

44. The transfer method according to claim 42, wherein the release layer between an auxiliary carrier and the electronic components is structured such that only unstructured regions of the release layer selectively contact the subset of the electronic components on the first substrate while pressing the plurality of auxiliary carriers onto the electronic components.

45. An electronic arrangement comprising:
a plurality of auxiliary carriers arranged next to one another and at a distance from one another, which are connected to one another by a carrier tape, the auxiliary carriers being transparent to light;
a plurality of electronic components arranged in rows and columns on the auxiliary carriers, wherein a release layer is arranged between the electronic components and the auxiliary carriers, and wherein the release layer comprises at least one light absorption layer which at least partially decomposes under the light; and
a tensioning device attached to edges of the carrier tape and configured to tension the carrier tape between its edges and to allow the electronic arrangement to be accommodated.

46. The electronic arrangement according to claim 45, wherein the release layer comprises an adhesive layer, a carrier layer and the light absorption layer, and wherein the carrier layer is arranged between the adhesive layer and the light absorption layer.

47. The electronic arrangement according to claim 45, wherein the carrier tape comprises the release layer.

48. The electronic arrangement according to claim 45, wherein the carrier tape is arranged on a side opposite the release layer from the auxiliary carriers, and wherein the carrier tape is transparent.

49. The electronic arrangement according to claim 48, wherein the tensioning device is attached to edges of the release layer and configured to also tension the release layer between its edges.

50. The electronic arrangement according to claim 45, wherein the release layer is structured such that the release layer covers only the auxiliary carriers and regions between the auxiliary carriers remain free of the release layer.

51. The electronic arrangement according to claim 45, wherein the release layer between an auxiliary carrier and the electronic components arranged thereon is structured such that regions of the release layer between the electronic components on the release layer are at least partially removed.

52. The electronic arrangement according to claim 45, wherein the plurality of auxiliary carriers arranged next to one another and spaced apart from each other are flexibly connected to each other by the carrier tape.
